(19) United States
(12) Patent Application Publication
(10) Pub. No.: US 2024/0376597 A1
(43) Pub. Date: Nov. 14, 2024

(54) LIQUID PRECURSOR CONTAINERS, LIQUID PRECURSOR SYSTEMS AND SEMICONDUCTOR PROCESSING SYSTEMS HAVING LIQUID PRECURSOR CONTAINERS, AND METHODS OF DEPOSITING MATERIAL LAYERS USING LIQUID PRECURSORS

(71) Applicant: ASM IP Holding B.V., Almere (NL)

(72) Inventors: Fan Gao, Chandler, AZ (US); Krishnaswamy Mahadevan, Tempe, AZ (US); Peipei Gao, Chandler, AZ (US); Xing Lin, Chandler, AZ (US); Jingxuan Lyu, Chandler, AZ (US)

(21) Appl. No.: 18/660,759

(22) Filed: May 10, 2024

Related U.S. Application Data
(60) Provisional application No. 63/501,384, filed on May 10, 2023.

(51) Int. Cl. C23C 16/448; C23C 16/52; C30B 25/14; H01L 21/02

(52) U.S. Cl. CPC C23C 16/448; C23C 16/52; C30B 25/14; H01L 21/02532; H01L 21/0262

(57) ABSTRACT

A liquid precursor container is provided. The liquid precursor container includes an inner container, an outer container, and a baffle member. The inner container has an inner base portion, an inner intermediate portion extending upwards from the inner base portion, and an inner lid portion coupled to the inner base portion by the inner intermediate portion. The outer container has an outer base portion spaced apart from the inner base portion of the inner container and an outer intermediate portion extending upwards from the outer base portion and about the inner intermediate portion of the inner container. The baffle member is arranged between the inner intermediate portion of the inner container and the outer intermediate portion of the outer container, extends upwards from the outer base portion of the outer container, and terminates between the inner lid portion and the inner base portion of the inner container.

### CROSS-REFERENCE TO RELATED APPLICATION(S)

This application claims the benefit of U.S. Provisional Application 63/501,384 filed on May 10, 2023, the entire contents of which are incorporated herein by reference.

### FIELD OF INVENTION

The present disclosure relates to fabricating semiconductor device. More particularly, the present disclosure relates to depositing material layers onto substrates using liquid precursors in semiconductor processing systems during the fabrication of semiconductor devices.

### BACKGROUND OF THE DISCLOSURE

Material layers are commonly deposited onto substrates during the fabrication of semiconductor devices, such as during the fabrication of integrated circuit and power electronic semiconductor devices. Material layer deposition is generally accomplished by supporting a substrate within a reactor, heating the substrate to a desired material layer deposition temperature, and providing a material layer precursor to the reactor at a desired flow rate. The substrate is exposed to the material layer precursor within the reactor under environmental conditions which cause a material layer to deposit onto the substrate. Once the material develops properties desired for the semiconductor device being fabricated flow the material layer precursor to the reactor ceases and the substrate removed from the reactor so that it can undergo further processing, as appropriate for the semiconductor device being fabricated.

In some deposition processes, the material layer may be deposited using a gaseous material layer precursor, i.e., material layer precursors that adopt a gaseous state at standard temperature and pressure. For example, silicon-containing gaseous precursors such as silane (SiH₄) may be employed in material layer deposition operations where silicon-containing material layers are deposited onto substrates. Dopant-containing gaseous precursors, such as arsine (AsH₃), may be employed where doped material layers are deposited onto substrates. While generally satisfactory for their intended purpose, silicon-containing gaseous precursors may limit throughput and/or require relatively high deposition temperatures in comparison to silicon-containing liquid precursors (i.e., precursors that adopt a liquid state at standard temperature and pressure), and dopant containing gaseous precursors may be hazardous to human health, adding cost and complexity to the semiconductor processing systems incorporating the gas phase reactor employed for the material layer deposition operation.

Liquid precursors, while potentially enabling relatively high throughput and/or lower deposition temperature (in the case of silicon-containing liquid precursors), and lower cost and more simple semiconductor processing system arrangements, require that the liquid precursor be converted from liquid state to a gaseous state prior to provision to a gas phase reactor. Conversion typically requires remote vaporization and communication to the gas phase reactor through a fluid system with environmental control features to prevent condensation of the vaporized liquid precursor, adding cost and complexity to the semiconductor processing system. Conversion may also require the employment of high precision vapor concentration sensors, further adding cost and complexity to the semiconductor processing systems employed to perform material layer deposition using the liquid precursor.

Such systems and methods have generally been considered suitable for their intended purpose. However, there remains a need in the art for improved liquid precursor containers, liquid delivery and semiconductor processing systems having liquid precursor containers, and methods of depositing material layers. The present disclosure provides a solution to this need.

### SUMMARY OF THE DISCLOSURE

A liquid precursor container is provided. The liquid precursor container includes an inner container, an outer container, and a baffle member. The inner container has an inner base portion, an inner intermediate portion extending upwards from the inner base portion, and an inner lid portion coupled to the inner base portion by the inner intermediate portion. The outer container has an outer base portion spaced apart from the inner base portion of the inner container and an outer intermediate portion extending upwards from the outer base portion and about the inner intermediate portion of the inner container. The baffle member is arranged between the inner intermediate portion of the inner container and the outer intermediate portion of the outer container, extends upwards from the outer base portion of the outer container, and terminates between the inner lid portion and the inner base portion of the inner container.

In addition to one or more of the features described above, or as an alternative, further examples may include that the inner base portion of the inner container is spaced apart from the outer base portion of the outer container by a pumping chamber. A circulation pump may be arranged within the pumping chamber.

In addition to one or more of the features described above, or as an alternative, further examples may include that the baffle member and the inner intermediate portion of the inner container define therebetween an upward flow channel spanning the intermediate portion of the inner container, that the outer intermediate portion of the outer chamber and the baffle member define therebetween a downward flow channel spanning the intermediate portion of the inner container, and that the pumping chamber fluidly couples the downward flow channel to the upward flow channel to circulate an immersion fluid impounded within the outer container about the inner container.

In addition to one or more of the features described above, or as an alternative, further examples may include an immersion fluid impounded within the outer container. The baffle member and the inner container may be submerged within the immersion fluid.

In addition to one or more of the features described above, or as an alternative, further examples may include a carrier gas conduit, a plug member, an outlet conduit, and a probe member. The carrier gas conduit may be sealably fixed within the inner lid portion of the inner container and extend toward the inner base portion of the inner container. The plug member may be removably fixed within the inner lid portion of the inner container. The outlet conduit may be sealably fixed within the inner lid portion of the inner container. The probe member sealably fixed within the inner lid portion of the inner container and extend toward the inner base portion of the inner container.

In addition to one or more of the features described above, or as an alternative, further examples may include a hinge member, an outer lid, and an immersion fluid temperature sensor. The hinge member may be connected to the outer intermediate portion of the outer container. The outer lid may be connected to the hinge member and movable between a first position and a second position, the outer lid separating the inner container from an external environment outside of the liquid precursor container, the inner container exposed to the external environment and removably from the outer container in the second position. The immersion fluid temperature sensor may be seated in the outer lid and extend into a downward flow channel defined between the baffle member and the outer intermediate portion of the outer container.

In addition to one or more of the features described above, or as an alternative, further examples may include an immersion fluid and a dopant-containing liquid precursor. The immersion fluid may be impounded within the outer container. The inner container may be submerged within the immersion fluid. The dopant-containing liquid precursor may be contained within the inner container and reactive with the immersion fluid impounded within the outer container.

In addition to one or more of the features described above, or as an alternative, further examples may include an immersion fluid and a silicon-containing liquid precursor. The immersion fluid may be impounded within the outer container. The inner container may be submerged within the immersion fluid. The silicon-containing liquid precursor may be contained within the inner container and reactive with the immersion fluid.

In addition to one or more of the features described above, or as an alternative, further examples may include a thermoelectric cooler (TEC) and a chill plate. The thermoelectric cooler may be connected to the outer base portion of the outer container. The chill plate may be connected to the TEC and therethrough to the outer base portion of the outer container.

In addition to one or more of the features described above, or as an alternative, further examples may include a carrier gas source and a gas phase reactor. The carrier gas source may be connected to the inner container of the liquid precursor container. The gas phase reactor may have a single-wafer crossflow arrangement, may be connected to the inner container of the liquid precursor container, and fluidly coupled through inner container to the carrier gas source.

In addition to one or more of the features described above, or as an alternative, further examples may include that the inner container is a U.S. DOT 4B-compliant container, and that the outer container may not be a U.S. DOT 4B-compliant container.

A liquid precursor system is provided. The liquid precursor system includes an enclosure body, a vent source, a coolant circuit, and a coolant source. The enclosure body may have a ventilated chamber with a container seat and a liquid precursor container as described above arranged within the ventilated chamber and removably supported at the container seat. The vent source may be connected to the ventilated chamber, the coolant circuit may be connected to the liquid precursor container, and the coolant source may connect to coolant circuit and remote from the enclosure body.

In addition to one or more of the features described above, or as an alternative, further examples may include that the liquid precursor container is connected to a gas phase reactor and that enclosure body is than about three (3) meters from the gas phase reactor.

In addition to one or more of the features described above, or as an alternative, further examples may include a carrier gas mass flow controller (MFC) connected to the inner container; a vapor pressure concentration sensor (VPCS) connected the inner container and fluidly coupled by the inner container to the carrier gas MFC; a vaporized liquid precursor MFC connected to the VPCS and therethrough to the carrier gas MFC via the inner container; and a liquid precursor contained within the liquid precursor container selected from a group including trisilane (Si₃H₆), tetrasilane (Si₄H₁₀), trichlorosilane (HCl₃Si), and tertiarybutylarsine (C₄H₁₁As).

In addition to one or more of the features described above, or as an alternative, further examples may include that the container seat is a first container seat, that the liquid precursor container is a first liquid precursor container, and that a second liquid precursor container removably fixed at the second container seat and a changeover arrangement connecting the second liquid precursor container with the first liquid precursor container.

A material layer deposition method is provided. The material layer deposition method includes, at a semiconductor processing system including a gas phase reactor and a liquid precursor container as described above, vaporizing a liquid precursor contained within the inner container, providing a flow of the vaporized liquid precursor to the gas phase reactor, and depositing a material layer onto the substrate using the vaporized liquid precursor with an epitaxial deposition technique.

In addition to one or more of the features described above, or as an alternative, further examples may include transferring heat between the liquid precursor and an external environment outside of the liquid precursor container by receiving a liquid precursor temperature measurement indicative of temperature of the liquid precursor contained within the inner container, comparing the liquid precursor temperature measurement to a predetermined liquid precursor temperature value, and throttling heat transfer between the liquid precursor and an environment external to the liquid precursor container using a thermoelectric cooler connected to the outer base portion of the outer container when differential between the liquid precursor measurement and the predetermined liquid precursor temperature value is greater than a predetermined liquid precursor temperature differential value.

In addition to one or more of the features described above, or as an alternative, further examples may include receiving a liquid precursor level measurement indicative of level of the liquid precursor contained within the liquid precursor container. One or more of (a) the liquid precursor temperature measurement and (b) the predetermined liquid precursor temperature value may be adjusted using the liquid precursor level measurement.

In addition to one or more of the features described above, or as an alternative, further examples may include transferring heat between an immersion fluid impounded within the outer container and within which the inner container is submerged and an external environment by receiving an immersion fluid temperature measurement indicative of temperature of the immersion fluid, comparing the immersion fluid temperature measurement to a predetermined immersion fluid temperature value, and throttling heat transfer between the immersion fluid and the environment external to the liquid precursor container using the thermoelectric cooler when differential between the immersion fluid and the predetermined immersion fluid temperature value is greater than a predetermined immersion fluid differential value.

In addition to one or more of the features described above, or as an alternative, further examples may include receiving a liquid precursor level measurement indicative of liquid precursor level within the inner container; comparing the liquid precursor level measurement to a predetermined liquid precursor level measurement; and one or more of (a) providing a user output to a user interface, (b) providing a changeover to a changeover arrangement to switch source of the vaporized liquid precursor, and (c) refill the inner container ex-situ with additional liquid precursor.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic diagram of a semiconductor processing system with a liquid precursor system and a gas phase reactor in accordance with the present disclosure, showing a liquid precursor container providing a flow of vaporized liquid precursor to the gas phase reactor;

FIG. 2 is a side view of the gas phase reactor of FIG. 1 according to an example of the present disclosure, schematically showing an epitaxial layer being deposited onto a substrate using the flow of the vaporized liquid precursor provided by the liquid precursor container;

FIG. 3 is a side view of the liquid precursor system of FIG. 1 according to an example of the present disclosure, schematically showing the liquid precursor container removable supported within a ventilated cabinet for cooling utilizing a chiller;

FIG. 4 is an exploded view of the liquid precursor container of FIG. 1 according to an example of the present disclosure, schematically showing a thermoelectric cooler and a chill plate exploded away from the liquid precursor container;

FIG. 5 is a plan view of the view of the inner lid portion of the inner container of the liquid precursor container of FIG. 1, schematically showing apertures to communicate fluids into and out of the inner container;

FIG. 6 is a plan view of the view of the outer lid of the outer container of the liquid precursor container of FIG. 1, schematically showing passthroughs for conduits and a sensors to communicate fluids into and out of the inner container as well as to provide temperature and level measurements from within the liquid precursor container;

FIG. 7 is a cross-sectional sectional view of the liquid precursor container of FIG. 1 according to an example of the present disclosure, schematically showing a liquid precursor contained within the inner container being vaporized using a carrier while being cooled by liquid coolant impounded within the outer container;

FIG. 8 is a block diagram of inputs and outputs to a controller of the liquid precursor system of FIG. 1, schematically showing liquid precursor temperature measurements, liquid coolant temperature measurements, and liquid level measurements being used to control temperature of the liquid precursor; and

FIGS. 9-13 are a block diagram of a method of depositing a material layer in a gas phase reactor using a liquid precursor, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

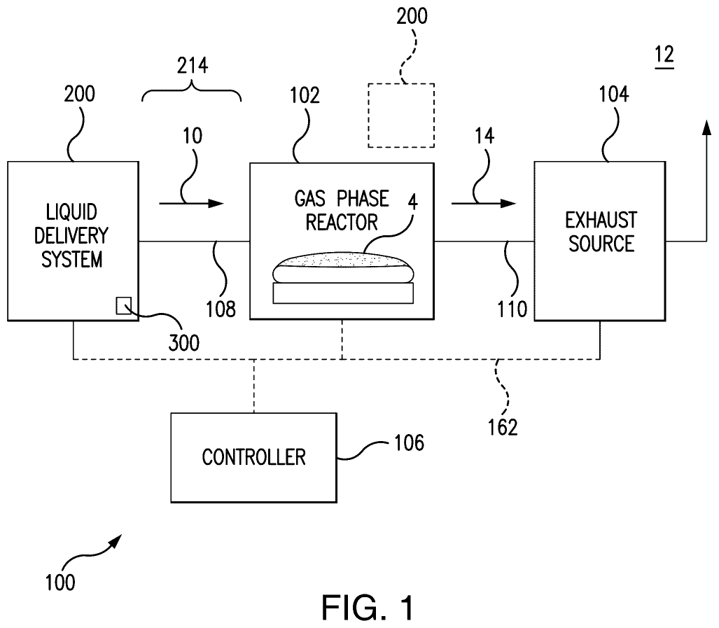

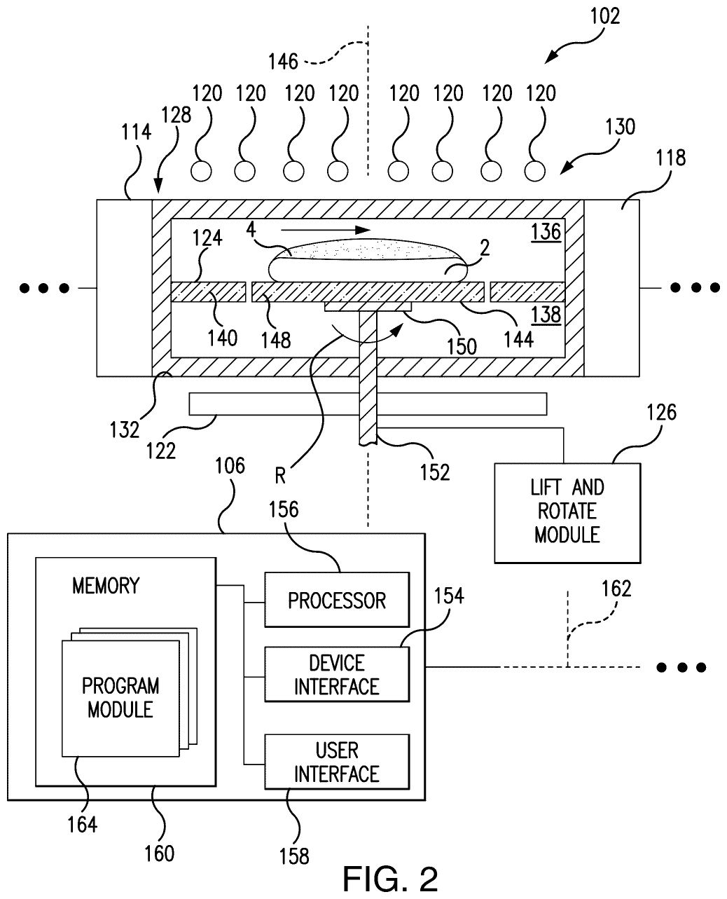

Reference will now be made to the drawings wherein like reference numerals identify similar structural features or aspects of the subject disclosure. For purposes of explanation and illustration, and not limitation, a partial view of an example of a liquid precursor container in accordance with the present disclosure is shown in FIG. 1 and is designated generally by reference characters 300. Other examples of liquid precursor containers, liquid precursor systems and semiconductor processing systems including liquid precursor containers, and methods of depositing material layers using vaporized liquid precursors in accordance with the present disclosure, or aspects thereof, are provided in FIGS. 2-13, as will be described. The systems and methods of the present disclosure may be used to deposit material layers onto substrates in gas phase reactors using vaporized liquid precursors, such as dopant-containing material layers using vaporized dopant-containing liquid precursors in single-wafer gas phase reactors having cross flow arrangements, though the present disclosure is not limited to dopant-containing liquid precursors or reactor arrangement in general.

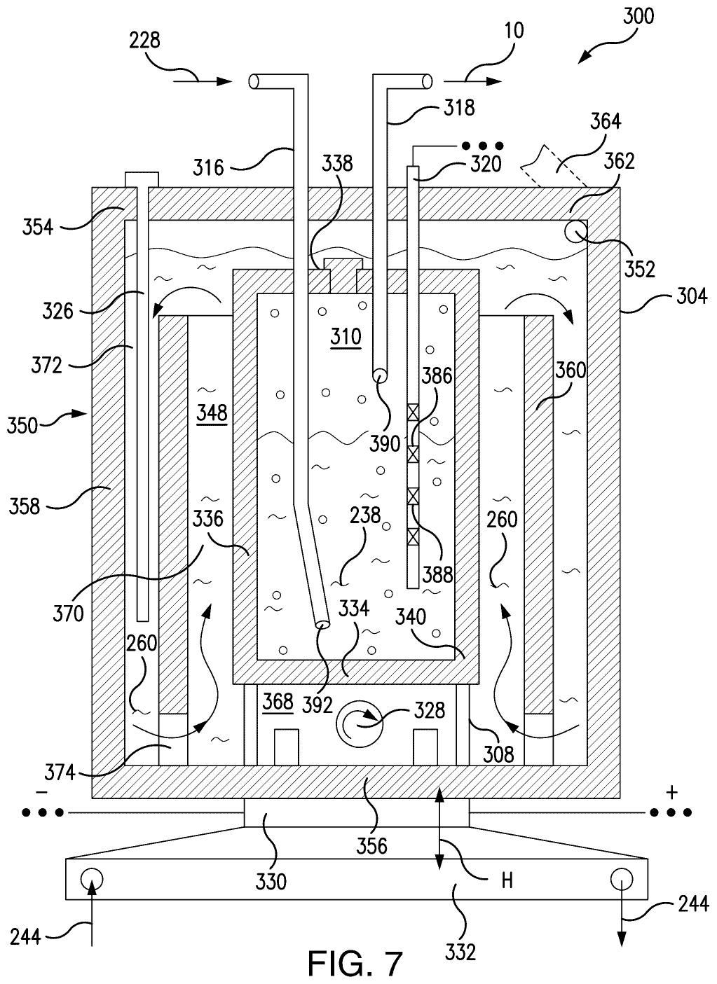

Referring to FIG. 1, a semiconductor processing system 100 is shown. The semiconductor processing system 100 includes a liquid precursor system 200 (e.g., a liquid precursor delivery system), a gas phase reactor 102, an exhaust source 104, and a controller 106. The liquid precursor system 200 is configured to provide a vaporized liquid precursor 10 to the gas phase reactor 102 and is connected to the gas phase reactor 102 by a precursor supply conduit 108. The gas phase reactor 102 is configured to deposit a material layer 4 onto a substrate 2 supported within the gas phase reactor 102 using the vaporized liquid precursor 10 and is connected to the exhaust source 104 by an exhaust conduit 110. The exhaust source 104 is configured to communicate residual precursor and/or reaction products 14 to the external environment 12, is fluidly coupled to an external environment 12 outside of the semiconductor processing system 100, and may include one or more of a vacuum pump and a scrubber or abatement apparatus 112. The controller 106 is operably connected to one or more of the liquid precursor system 200, the gas phase reactor 102, and the exhaust source 104 and in this respect may be configured to control vaporization of a liquid precursor 238 (shown in FIG. 7) contained within the liquid precursor container 300. In certain examples, the material layer 4 may include silicon and/or a dopant. In accordance with certain examples, the material layer 4 may be an epitaxial material layer. It is also contemplated that the material layer 4 may be an silicon-containing epitaxial material layer, which may also include a dopant.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the gas phase reactor 102 and the controller 106 are shown according to an example of the present disclosure. In the illustrated example the gas phase reactor 102 has a single-wafer crossflow arrangement and in this respect includes an injection flange 114, a chamber body 116, and an exhaust flange 118. In further respect, the gas phase reactor 102 further includes an upper heater element array 120, a lower heater element array 122, a divider 124, and a lift and rotate module 126. Although shown and described herein as including certain elements and a having a specific arrangement, it is to be understood and appreciated that the gas phase reactor 102 may include other elements and/or exclude certain elements described herein, or have another arrangement, and remain within the scope of the present disclosure.

The chamber body 116 has an injection end 128 and a longitudinally opposite exhaust end 130, is formed from a transparent material 132 (e.g., a material transmissive to electromagnetic radiation within an infrared waveband), and may include a plurality of external ribs extending laterally about an exterior of the chamber body 116 and longitudinally spaced apart from one another between the injection end 128 and the exhaust end 130 of the chamber body 116. The injection flange 114 is connected to the injection end 128 of the chamber body 116 and fluidly couples the precursor supply conduit 108 to an interior 134 of the gas phase reactor 102. The exhaust flange 118 is connected to the exhaust end 130 of the chamber body 116, is further connected to the exhaust conduit 110, and fluidly couples the interior 134 of the chamber body 116 therethrough to the exhaust source 104 (shown in FIG. 1).

The upper heater element array 120 is supported above the chamber body 116 and includes a plurality of heater elements configured to heat a substrate (e.g., the substrate 2) when seated within the interior 134 of the chamber body 116. In this respect the plurality of heater elements of the upper heater element array 120 are configured to emit electromagnetic radiation within an infrared waveband, which the transparent material 132 communicates into the interior 134 of the chamber body 116. The lower heater element array 122 is similar to the upper heater element array 120, is additionally supported below the chamber body 116, and also configured to heat the substrate 2 during deposition of the material layer 4 (e.g., an epitaxial material layer) when the substrate 2 is seated within the interior 134 of the chamber body 116. In certain examples the upper heater element array 120 and the lower heater element array 122 may include linear filament heat lamps. In accordance with certain examples, the upper heater element array 120 and/or the lower heater element array 122 may include spot lamps and remain within the scope of the present disclosure.

The divider 124 is fixed within the chamber body 116 and divides the interior 134 of the chamber body 116 into an upper chamber 136 and a lower chamber 138. The divider 124 is further formed from an opaque material 140, e.g., a material opaque to electromagnetic radiation within an infrared waveband, and defines an aperture 142. It is contemplated that the aperture 142 fluidly coupled the upper chamber 136 of the chamber body 116 to the lower chamber 138 of the chamber body 116, and that a substrate support 144 be arranged within aperture 142. The substrate support 144 is configured to support the substrate 2 during deposition of the material layer 4 onto the substrate 2 and in this respect is supported for rotation R about a rotation axis 146 within the aperture 142. In further respect, the substrate support 144 may be formed from an opaque material 148, e.g., a material opaque to electromagnetic radiation within an infrared waveband, and may include a susceptor body. In certain examples, the opaque material 140 may include a bulk silicon carbide material. In accordance with certain examples, the opaque material 148 may include a bulk carbonaceous material with a silicon carbide material, such as bulk graphite or pyrolytic carbon by way of non-limiting example. It is also contemplated that, in accordance with certain examples, the substrate support 144 may be operably connected to the lift and rotate module 126 by a support member 150 and a shaft member 152, which may be arranged along the rotation axis 146 and fixed in rotation relative to the substrate support 144, and which may also be formed from the transparent material 132.

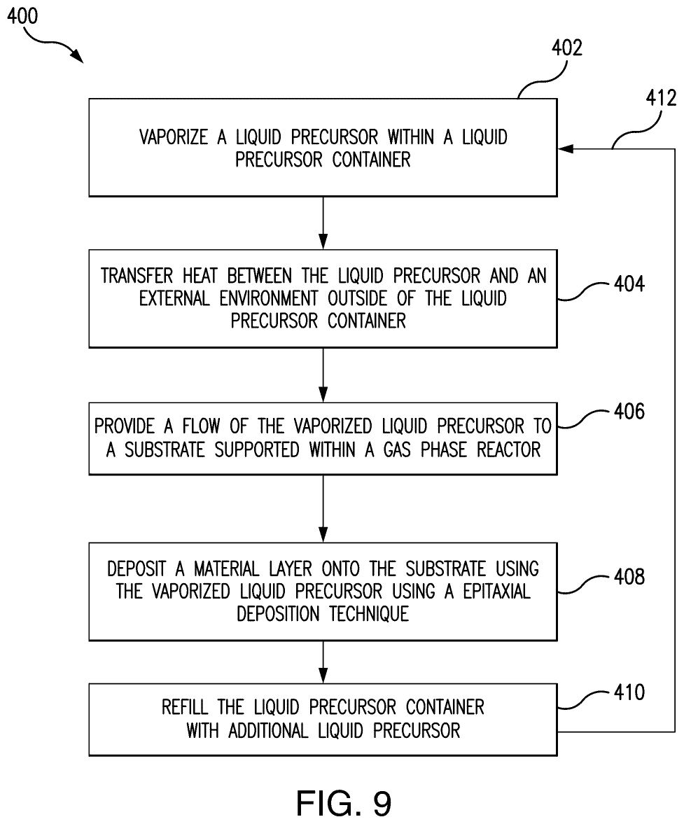

The controller 106 includes a device interface 154, a processor 156, a user interface 158, and a memory 160. The device interface 154 connects the processor 156 to a wired or wireless link 162 and therethrough to the liquid precursor system 200 and the gas phase reactor 102. The processor 156 is in turn operably connected to the user interface 158, for example, to receive a user input and/or provide a user output therethrough, and is disposed in communication with the memory 160. The memory 160 includes a non-transitory machine-readable medium having a plurality of program modules 164 recorded thereon that, when read by the processor 156, cause the processor 156 to execute certain operations. Among the operations are operations of a material layer deposition method 400 (shown in FIG. 9) using a liquid precursor, as will be described. Although shown and described herein as having a specific architecture, it is to be understood and appreciated that other controller architectures may be employed, e.g., distributed architectures, and remain within the scope of the present disclosure.

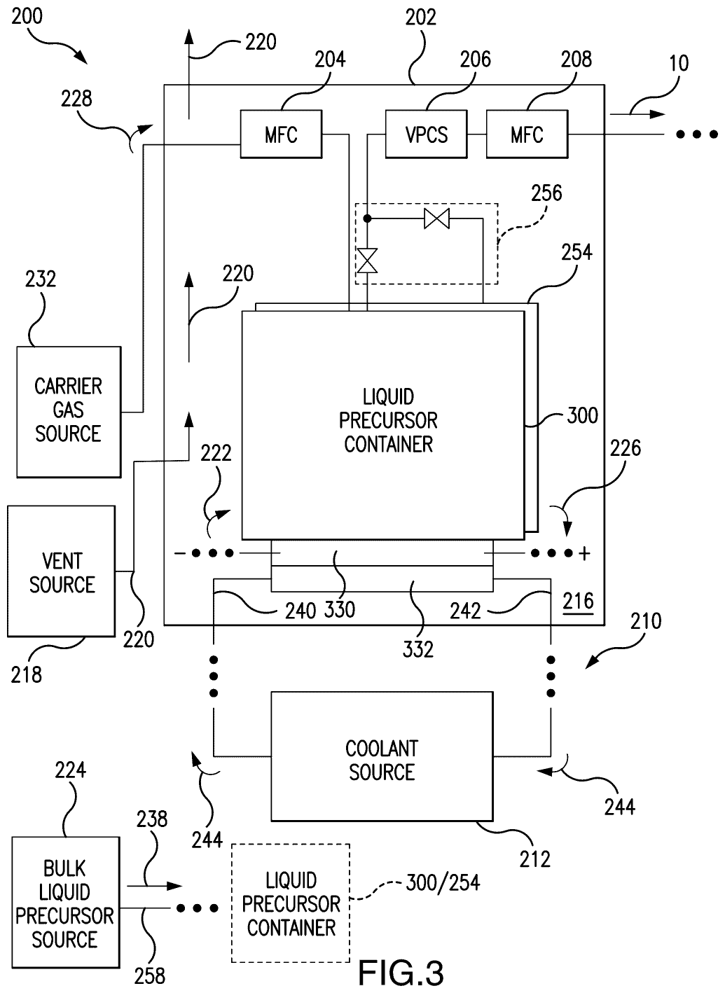

With reference to FIG. 3, the liquid precursor system 200 is shown. The liquid precursor system 200 generally includes an enclosure body 202 and the liquid precursor container 300. As shown and described herein the liquid precursor system 200 also includes a carrier gas mass flow controller (MFC) or pressure controller (PC) 204, a vapor pressure concentration sensor (VPCS) 206, a vaporized liquid precursor MFC 208, a coolant circuit 210, and coolant source 212. Although shown and described herein as having certain elements and a particular arrangement, it is to be understood and appreciated that liquid precursor system 200 may include other elements and/or exclude elements shown and described herein in other examples, or have different arrangements, in other examples and remain within the scope of the present disclosure.

The enclosure body 202 is configured for arrangement proximate to (or within) the footprint of the semiconductor processing system 100 (shown in FIG. 1). In this respect it is contemplated that the enclosure body be arranged within about three (3) meters of the semiconductor processing system 100, for example, spaced apart from the gas phase reactor 102 (shown in FIG. 1) by a spacing distance 214 (shown in FIG. 1) that is less than about three (3) meters. In accordance with certain examples, the enclosure body 202 may be supported above or below the semiconductor processing system 100, for example above or below the gas phase reactor 102, a footprint of the liquid precursor system 200 overlaying (and within) a footprint of the semiconductor processing system 100. As will be appreciated by those of skill in the art in view of the present disclosure, arranging the liquid precursor system 200 proximate the semiconductor processing system 100 limits (or eliminates) risk that vaporized liquid precursor condenses within the precursor supply conduit 108 (shown in FIG. 1), simplifying the semiconductor processing system 100 by limiting (or eliminating) the need to incorporate temperature control features on the precursor supply conduit 108. As will also be appreciated by those of skill in the art in view of the present disclosure, it can also limit footprint size of the semiconductor processing system 100, limiting cost of the semiconductor processing system 100.

The enclosure body 202 may be configured to enclose to enclose the liquid precursor container 300, the carrier gas MFC or PC 204, the VPCS 206, and the vaporized liquid precursor MFC 208, for example, within a ventilated atmosphere. In this respect the enclosure body 202 may define a ventilated chamber 216 within its interior. The enclosure body 202 may be connected to a vent source 218, for example via a duct, the vent source 218 in turn configured to provide a flow of a vent fluid 220 to the enclosure body 202 and therethrough the ventilated chamber 216. It is contemplated that the liquid precursor container 300 may be removably fixed within the ventilated chamber 216 at a container seat 222 for removal and ex-situ refilling outside of the enclosure body 202 at a bulk liquid precursor source 224 remote from the semiconductor processing system 100 (shown in FIG. 1). As will be appreciated by those of skill in the art in view of the present disclosure, ventilating the liquid precursor container 300 limits risk attendant with liquid precursors reactive with moisture and air contained within the liquid precursor container 300, such as in the event residual liquid precursor is exposed to the atmosphere within ventilated cabinet during removal and replacement of the liquid precursor container 300. In certain examples, the container seat 222 may be a first container seat 222 and the enclosure body 202 may include one or more second container seats 226 similarly configured to removably fix therein a second liquid precursor container 254, which may be similar to the first liquid precursor container 300 and additionally connected to the precursor supply conduit 108 (shown in FIG. 1) by an changeover arrangement 256.

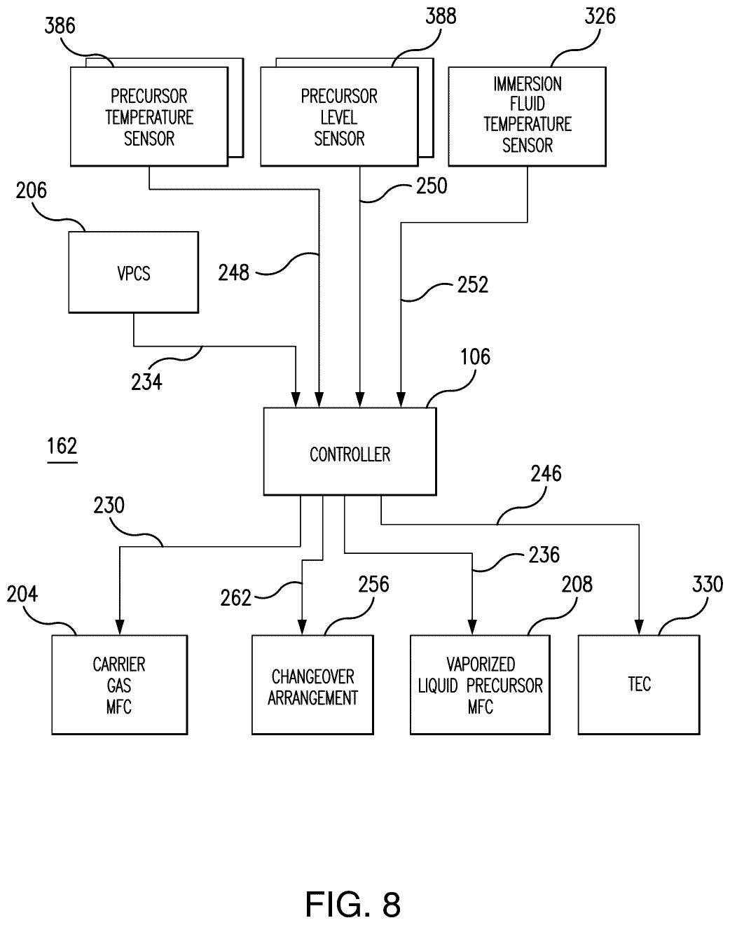

The carrier gas MFC or PC 204 is arranged within the ventilated chamber 216 and is configured to provide a flow of a carrier gas 228 to the liquid precursor container 300. In this respect the carrier gas MFC or PC 204 may be operably associated with the controller 106 (shown in FIG. 1) and configured to throttle flow rate of the carrier gas 228 to the liquid precursor container 300 using a carrier gas flow rate target 230 (shown in FIG. 8), which may be provided by the controller 106, for example via the wired or wireless link 162 (shown in FIG. 1). The carrier gas MFC or PC 204 may further connect the liquid precursor container 300 to a carrier gas source 232, which may provide the carrier gas 228 to the liquid precursor container 300. In certain examples, the carrier gas 228 may comprise (or consist of or consist essentially of) an inert gas. In this respect the carrier gas 228 may include nitrogen (N₂) gas or a noble gas. Examples of suitable noble gases include helium (He), argon (Ar), krypton (Kr). It is also contemplated that the carrier gas 228 may comprise (or consist of or consist essentially of) hydrogen (H₂) gas or a mixture of one or more of the aforementioned gases and remain within the scope of the present disclosure. Examples of suitable MFC devices include GP200 Series MFC devices, available from Brooks Instrument, LLC. of Hatfield, Pennsylvania.

The VPCS 206 and the vaporized liquid precursor MFC 208 are configured to provide the flow of the vaporized liquid precursor 10 to the gas phase reactor 102 (shown in FIG. 1) and in this respect are arranged within the ventilated chamber 216. In further respect the VPCS 206 and the vaporized liquid precursor MFC 208 connect the liquid precursor container 300 to the gas phase reactor 102 through the precursor supply conduit 108 (shown in FIG. 1), and may be connected fluidly in series with one another between the liquid precursor container 300 and the gas phase reactor 102. It is contemplated that the VPCS 206 be disposed in communication with the controller 106 to provide a precursor concentration measurement 234 (shown in FIG. 8) to the controller 106, for example, via the wired or wireless link 162 (shown in FIG. 1). It is also contemplated that the vaporized liquid precursor MFC 208 be operatively associated with the controller 106 to throttle mass flow of precursor to the gas phase reactor 102 using a vaporized liquid precursor flow rate target 236 (shown in FIG. 8) received from the controller 106, for example also using the wired or wireless link 162 (shown in FIG. 1). Examples of suitable VPCS devices include IR-300 vapor concentration monitor devices, available from Horiba Ltd. of Kyoto, Japan.

The liquid precursor container 300 is configured to make-up the flow of vaporized liquid precursor 10 provided to the gas phase reactor 102 using the carrier gas 228 and a charge of a liquid precursor 238 contained within the liquid precursor container 300. In certain examples, the liquid precursor 238 may comprise (e.g., consist of or consist essentially of) a dopant-containing liquid precursor. In this respect the liquid precursor 238 may include a p-type dopant such as boron (B), aluminum (Al), gallium (Ga), and indium (In). In further respect the liquid precursor 238 may include an n-type dopant such as phosphorous (P), arsenic (As), antimony (Sb), bismuth (Bi), and lithium (Li). In accordance with certain examples, the liquid precursor 238 may include a dopant that, when present in a gaseous precursor, requires containment features unnecessary when provided as a liquid precursor, such as tertiarybutylarsine (C₄H₁₁As). As will be appreciated by those of skill in the art in view of the present disclosure, this can limit the risk potentially associated with deposition processes employed to deposit material layers including such dopants. As will also be appreciated by those of skill in the art in view of the present disclosure, this can also simplify semiconductor processing systems employed to deposit such material layers by limiting (or eliminating) the need for safety features otherwise required where the dopant is provided using a gaseous precursor.

In certain examples the liquid precursor 238 may comprise (e.g., consist of or consist essentially of) a silicon-containing liquid precursor such as trichlorosilane (Cl₃HSi). In accordance with certain examples, the liquid precursor may include a high order silane (i.e., a silane compound having more than two silicon atoms per molecule), such as a silicon-containing liquid precursor that enables deposition of a silicon-containing epitaxial material layer at a greater deposition rate than a silicon-containing gaseous precursor with two or less silicon atoms per molecule. Examples of suitable silicon-containing liquid precursors include trisilane (Si₃H₆) and/or tetrasilane (Si₄H₁₀). As will be appreciated by those of skill in the art in view of the present disclosure, employment of such silicon-containing liquid precursors allow the material layer 4 (shown in FIG. 1) to deposited at a high deposition relative to deposition processes employing silicon-containing gaseous precursors, enabling the semiconductor processing system 100 (shown in FIG. 1) to provide greater throughput and/or operate at lower deposition temperature rate than semiconductor processing systems employing silicon-containing gaseous precursors, limiting cost of ownership of the semiconductor processing system 100 relative to semiconductor processing systems employing silicon-containing gaseous precursors.

The coolant circuit 210 is configured to thermally couple the liquid precursor container 300 to the coolant source 212, e.g., a remote coolant source located outside of a cleanroom environment housing the semiconductor processing system 100 (shown in FIG. 1), to control temperature of the liquid precursor 238 contained within liquid precursor container 300. In this respect the coolant circuit 210 includes a coolant supply conduit 240 and a coolant return conduit 242. The coolant supply conduit 240 connects the coolant source 212 to the liquid precursor container 300 to provide a flow of a liquid coolant 244 to the liquid precursor container 300. The coolant return conduit 242 connects the liquid precursor container 300 to the coolant source 212 to return the flow of the liquid coolant 244 to the coolant source 212. In certain examples the liquid coolant 244 may comprise (or consist of or consist essentially of) water. In accordance with certain examples, the liquid coolant 244 may comprise (or consist of or consist essentially of) glycol and/or alcohol. It is also contemplated that, in accordance with certain examples, the liquid coolant 244 provided to the liquid precursor container 300 may comprise (or consist of or consist essentially of) a perfluorinated coolant. Examples of suitable perfluorinated coolants include Fluorinert®, available from the 3M Company of Maplewood, Minnesota. Although shown and described herein as a coolant source 212, it is to be understood and appreciated that the coolant source 212 may be employed to heat the liquid precursor 238 contained within the liquid precursor container 300, as appropriate for the type of coolant and/or pressure and temperature conditions within the liquid precursor container 300.

In certain examples, the liquid precursor 238 contained within the liquid precursor container 300 may thermally couple to the liquid coolant 244 through a chill plate 332 and a thermoelectric cooler (TEC) 330. The chill plate 332 may be arranged within the ventilated chamber 216 and connect the coolant supply conduit 240 to the coolant return conduit 242. The TEC 330 may be arranged within the ventilated chamber 216 and connect the chill plate 332 to the liquid precursor container 300. The TEC 330 may be configured to throttle (e.g., increase or decrease) heat transfer between the liquid precursor 238 contained within the liquid precursor container 300 and the liquid coolant 244. In this respect TEC 330 may be operatively associated with the controller 106 (shown in FIG. 1) to throttle heat transfer between the liquid precursor 238 contained within the liquid precursor container 300 and the liquid coolant 244 using a TEC drive current 246 (shown in FIG. 8) provided to the TEC 330 by the controller 106. The controller 106 may in turn throttle (e.g., control magnitude and direction using a power source operatively associated with the controller 106) of the TEC drive current 246 using one or more of a liquid precursor temperature measurement 248 (shown in FIG. 8), a liquid precursor level measurement 250 (shown in FIG. 8), and an immersion fluid temperature measurement 252 (shown in FIG. 8) provided to the controller 106 by the liquid precursor container 300. Advantageously, having the ability to heat as well as cool the liquid precursor 238 using the TEC 330 can simplify arrangement of semiconductor processing systems employing the liquid precursor container 300, for example by limiting the number of parts required by eliminating the need for cooling-specific and heating-specific components in such semiconductor processing system.

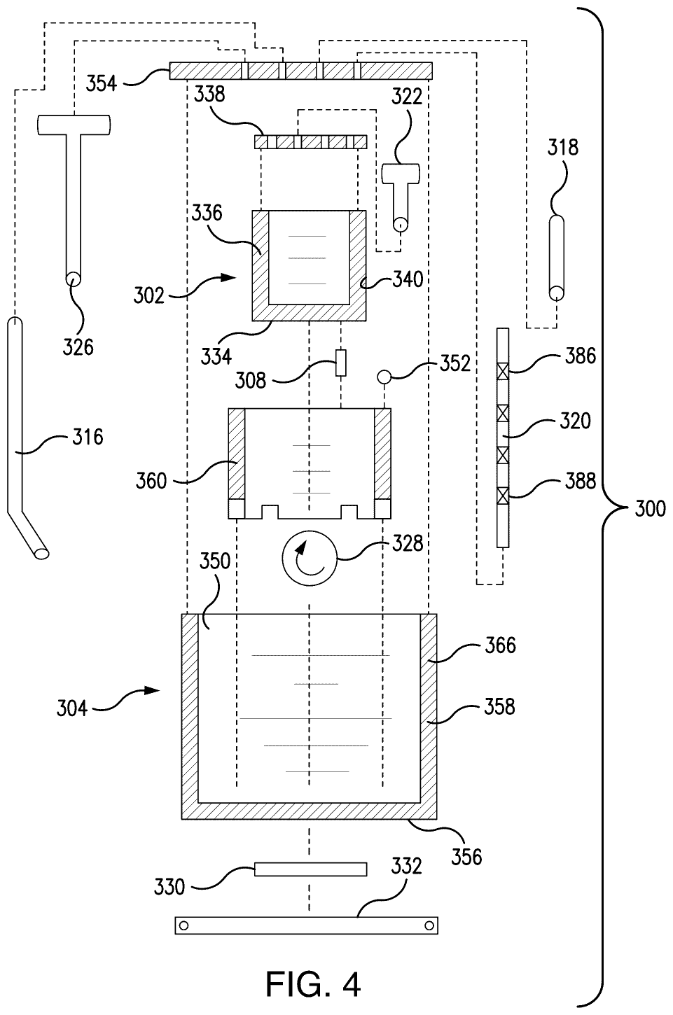

With reference to FIGS. 4-7, the liquid precursor container 300 is shown. In the illustrated example the liquid precursor container 300 includes the inner container 302 and the outer container 304. As shown and described herein the liquid precursor container 300 further includes a carrier gas conduit 316, an outlet conduit 318, a probe member 320, and a plug member 322. As also shown and described herein, the liquid precursor container 300 further includes a hinge member 324, an immersion fluid temperature sensor 326, a circulation pump 328, the thermoelectric cooler (TEC) 330, and the chill plate 332. Although shown and described herein including certain elements and having a specific arrangement, it is to be understood and appreciated that the liquid precursor container 300 may include other elements and/or exclude elements shown and described herein, or have an arrangement differing from that shown and described herein, and remain within the scope of the present disclosure.

The inner container 302 is configured to contain the liquid precursor 238 (shown in FIG. 3) for vaporization of the liquid precursor using the carrier gas 228 (shown in FIG. 3) and in this respect has an inner base portion 334, an inner intermediate portion 336, and an inner lid portion 338. The inner base portion 334 extends laterally within the outer container 304 and is supported within the outer container 304 by the stand or coupling 308. The inner intermediate portion 336 extends upwards from the inner base portion 334 and thereabout, and couples the inner lid portion 338 to the inner base portion 334 of the inner container 302. The inner lid portion 338 is fixed to the inner intermediate portion 336 of the inner container 302, spans the inner intermediate portion 336 of the inner container 302, and is coupled by the inner intermediate portion 336 to the inner base portion 334 of the inner container 302.

In certain examples, the inner container 302 may be formed from a metallic material 340. In this respect it is contemplated that the inner container 302 be formed from a material that is not reactive with any of the liquid precursor 238 (shown in FIG. 3), the carrier gas 228 (shown in FIG. 3), and the immersion fluid 260 (shown in FIG. 7) impounded within the liquid precursor container 300. Examples of suitable materials include aluminum alloys and stainless steel, such as 316L stainless steel. In accordance with certain examples, the inner container 302 may comply to a U.S. Department of Transportation regulation, such as 49 C.F.R. § 178 (2021). For example, the inner container 302 may be formed such that the inner container 302 is DOT 4B-compliant. Advantageously, compliance to such regulations and/or standards enables the inner container 302 to be immersed and/or submerged within the immersion fluid 260 notwithstanding the liquid precursor 238 contained within the inner container 302 being reactive with the immersion fluid 260. For example, the immersion fluid 260 may include (or consist of or consist essentially of) water, and the liquid precursor 238 may include a material reactive with immersion fluid 260.

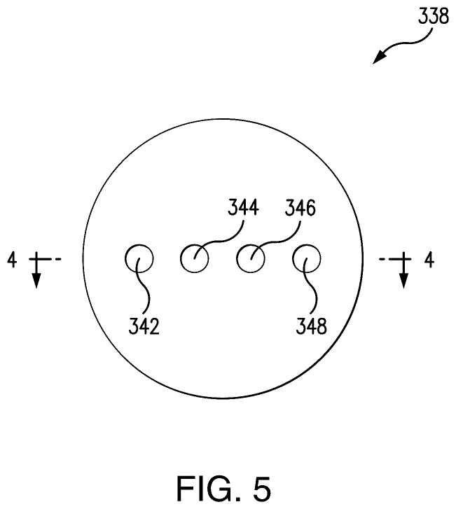

As shown in FIG. 5, the inner lid portion 338 of the inner container 302 (shown in FIG. 4) defines a carrier gas aperture 342, a refill aperture 344, an outlet conduit aperture 346, and a probe member aperture 348. The carrier gas aperture 342 extends through a thickness of the inner lid portion 338 and is configured to seat therein the carrier gas conduit 316 (shown in FIG. 4). The outlet conduit aperture 346 is offset from the carrier gas aperture 342 and is configured to seat therein the outlet conduit 318 (shown in FIG. 4). The probe member aperture 348 is offset from the outlet conduit aperture 346 and is configured to seat therein the probe member 320 (shown in FIG. 4). The refill aperture 344 is between the carrier gas aperture 342 and the outlet conduit aperture 346 and is configured to sealably seat therein the plug member 322 (shown in FIG. 4). It is contemplated that the refill aperture 344 be configured to sealably seat therein a refill conduit 258 (shown in FIG. 3) for refilling the inner container 302 ex-situ, i.e., subsequent to removal from the enclosure body 202 (shown in FIG. 3), for refilling with a flow of the liquid precursor 238 (shown in FIG. 3) received from the bulk liquid precursor source 224 (shown in FIG. 3).

Referring again to FIG. 4, the outer container 304 includes a tub body 350, a hinge member 352, an outer lid 354, and a baffle member 360. The tub body 350 has an outer base portion 356 and an outer intermediate portion 358. The outer base portion 356 laterally spans the inner base portion 334 of the inner container 302 and is spaced apart from the inner base portion 334 by the inner container 302 by the stand or coupling 308. The outer intermediate portion 35 further extends upwards from the outer base portion 356 of the outer container 304 and about the baffle member 360 of the outer container 304, and supports the hinge member 352 and the outer lid 354. In this respect it is contemplated that hinge member 352 be connected to an upper rim of the outer intermediate portion 358, that the outer lid 354 be connected to the hinge member 352 and therethrough the tub body 350, and that outer lid 354 be movable between a first position 362 (shown in FIG. 7) and a second position 364 (shown in FIG. 7). When in the first position 362 the outer lid 354 fluidly separates the interior of the outer container 304 from the external environment outside of the liquid precursor container 300. When in the second position 364 the outer lid 354 is spaced apart from the outer intermediate portion at an end opposite the hinge member 352. As will be appreciated by those of skill in the art in view of the present disclosure, this allows inner container 302 to be removed from the liquid precursor container 300, such as for refilling at the bulk liquid precursor source 224 (shown in FIG. 3).

The baffle member 360 is arranged between the inner container 302 and the outer container 304. In this respect the baffle member 360 extends upwards from the outer base portion 356 and about a portion of the inner intermediate portion 336 of the inner container 302, and is spaced apart from both the inner container 302 and the outer intermediate portion 358 of the outer container 304. It is contemplated that the baffle member 360 further terminate at location between the inner base portion 334 of the inner container 302 and the inner lid portion 338 of the inner container 302.

The tub body 350 may be formed from a metallic material 366. For example, the metallic material 366 forming the tub body 350 may be the same as the metallic material 340 forming in the inner container 302. Alternatively, the metallic material 366 forming the tub body 350 of the outer container 304 may be different than the metallic material 340 forming the inner container 302 of the liquid precursor container 300. In this respect it is contemplated that the inner container 302 may be formed from stainless steel and the tub body 350 may be formed from an aluminum alloy. Advantageously, forming the tub body 350 from an aluminum alloy may enhance control of heat transfer between the liquid precursor 238 contained within the inner container 302 and the external environment outside of the liquid precursor container 300 due to the heat transfer coefficient of aluminum alloys in relation to certain stainless materials.

The outer container 304 may, in certain examples, comply to a U.S. Department of Transportation standard. For example, the outer container 304 may be DOT 4B-compliant container. It is also contemplated that outer container 304 may not comply with DOT 4B. As will be appreciated by those of skill in the art in view of the present disclosure, forming the outer container 304 as a non-compliant DOT 4B container may simplify fabrication and/or limit cost of the liquid precursor container 300, for example, by limiting certification requirements.

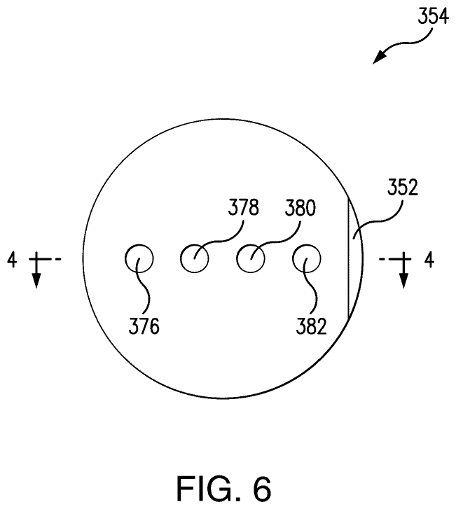

As shown in FIG. 6, the outer lid 354 has an immersion fluid temperature sensor seat 376 and defines therethrough a carrier gas conduit passthrough 378, an outlet conduit passthrough 380, and a probe member passthrough 382. The immersion fluid temperature sensor seat 376 is configured to removably fix the immersion fluid temperature sensor 326 (shown in FIG. 4) within a downward flow channel 372 (shown in FIG. 7). The carrier gas conduit passthrough 378 is registered to the carrier gas aperture 342 when the outer lid 354 (shown in FIG. 4) is in the first position 362 (shown in FIG. 1), and is configured to receive therethrough the carrier gas conduit 316. The probe member passthrough 382 is spaced apart from carrier gas conduit passthrough 378 by the outlet conduit passthrough 380, is registered to the probe member aperture 348 (shown in FIG. 5) when the outer lid 354 is in the first position 362, and is configured to receive therethrough the probe member 320 (shown in FIG. 4). The outlet conduit passthrough 380 is intermediate (e.g., laterally between) the carrier gas conduit passthrough 378 and the probe member passthrough 382, is registered to the probe member aperture 348 (shown in FIG. 5) when the outer lid 354 is in the first position 362, and receives therethrough the probe member 320 (shown in FIG. 4).

As shown in FIG. 7, it is contemplated that the inner base portion 334 of the inner container 302 and the outer base portion 356 of the outer container 304 define therebetween a pumping chamber 368. It is further contemplated that inner intermediate portion 336 of the inner container 302 and the baffle member 360 define therebetween an upward flow channel 370, that baffle member 360 and the outer intermediate portion 358 of the outer container 304 define therebetween the downward flow channel 372, and that the pumping chamber 368 fluidly couple the downward flow channel 372 to the upward flow channel 370. It is contemplated that the baffle member 360 define therethrough a plurality of return apertures 374 proximate to (e.g., bounded by) the outer base portion 356, and that the return apertures 374 fluidly couple the downward flow channel 372 to the pumping chamber 368. It is also contemplated that the circulation pump 328 be arranged within the pumping chamber 368, and that the circulation pump 328 be configured to immersion fluid received from the downward flow channel 372 via the return apertures 374 upwards through the upward flow channel 370 in a direction toward the outer lid 354 of the outer container 304.

It is contemplated that the TEC 330 be connected to the tub body 350 to transfer heat between the immersion fluid 260 and the chill plate 312. In this respect it is contemplated that the TEC 330 be connected to a lower surface of the outer base portion 356 of the tub body 350 to transfer heat H between the liquid precursor 238 and the liquid coolant 244 through the immersion fluid 260 during transit of the pumping chamber 368, for example during traverse of the return apertures 374 and/or the stand or coupling 308. Advantageously, arranging the TEC 330 adjacent to pumping chamber 368 enhances heat transfer between the immersion fluid 260 and the TEC 330 due to turbulence introduced into flow of the immersion fluid 260 within the pumping chamber 368 due to operation of the circulation pump 328 and fluid turning effects associated with the plurality of return apertures 374 defined by the baffle member 360 of the outer container 304 and/or the stand or coupling 308. The enhanced heat transfer provided by turbulent flow improves control of heat transfer between the liquid precursor 238 contained within the inner container 302 and the chill plate 332, which is connected to the TEC 330 and thermally coupled therethrough to the liquid precursor 238 via the immersion fluid 260 and the inner container 302.

The immersion fluid temperature sensor 326 may be submerged within the immersion fluid 260 impounded within the outer container 304 of the liquid precursor container 300. In this respect it is contemplated that the immersion fluid temperature sensor 326 be arranged within the downward flow channel 372 to provide the immersion fluid temperature measurement 252 (shown in FIG. 8) to the controller 106 (shown in FIG. 1). Advantageously, positioning the immersion fluid temperature sensor 326 improves accuracy of the immersion fluid temperature measurement 252 due to laminar flow conditions of the immersion fluid 260 within the downward flow channel 372. To further advantage, arrangement of the immersion fluid temperature sensor 326 within the downward flow channel 372 may further improve accuracy of the immersion fluid temperature measurement 252 (shown in FIG. 8) due to separation of the downward flow channel 372 from the upward flow channel 370 due to temperature change of the immersion fluid 260 during upward traverse of the inner intermediate portion 336 of the inner container 302.

The carrier gas conduit 316 extends through the carrier gas conduit passthrough 378 (shown in FIG. 6) and the carrier gas aperture 342 (shown in FIG. 5) and is sealably fixed within the carrier gas aperture 342, such as by a weld or fitting. The carrier gas conduit 316 further terminates at a carrier gas outlet 392, which may be proximate an upper surface of the inner base portion 334 of the inner container 302. It is contemplated that the carrier gas conduit 316 be configured to introduce the carrier gas 228 into the liquid precursor 238 contained within the inner container 302, the carrier gas 228 vaporizing a portion of the liquid precursor 238 (e.g., by bubbling therethrough) to enable vaporized liquid precursor resident within the inner container ullage space 310 to make up the flow of the vaporized liquid precursor 10 provided to the gas phase reactor 102 (shown in FIG. 1). In this respect it is contemplated that the carrier gas conduit 316 connect the carrier gas source 232 (shown in FIG. 3) to the inner container 302, for example, through the carrier gas MFC or PC 204 (shown in FIG. 3).

The outlet conduit 318 extends through the outlet conduit passthrough 380 (shown in FIG. 6) and the outlet conduit aperture 346 (shown in FIG. 5), is sealably fixed within the outlet conduit aperture 346, and is fluidly coupled to the inner container ullage space 310. In this respect it is contemplated that the outlet conduit 318 have an outlet conduit inlet 390, and that the outlet conduit 318 be connected to the gas phase reactor 102 (shown in FIG. 1) and therethrough to the exhaust source 104 (shown in FIG. 1) such that vaporized liquid precursor resident within the inner container ullage space 310 makeup the flow of the vaporized liquid precursor 10 provided to the gas phase reactor 102. In certain examples, the outlet conduit inlet 390 may be flush (e.g., coplanar) within the lower surface of inner lid portion 338 of the inner container 302, limiting height of the inner container 302 and simplifying packaging of the liquid precursor container 300 within the enclosure body 202 (shown in FIG. 3). In accordance with certain examples, the outlet conduit inlet 390 may be offset from the lower surface of the inner lid portion 338 in a direction toward the inner base portion 334 of the inner container 302. As will be appreciated by those of skill in the art in view of the present disclosure, offsetting the outlet conduit inlet 390 may limit (or eliminate) risk that liquid precursor become entrained within the flow the vaporized liquid precursor 10 provided to the gas phase reactor 102, for example, in the event that vaporized liquid condenses on the lower surface of the inner lid portion 338 of the inner container 302.

The probe member 320 extends through the probe member passthrough 382 (shown in FIG. 6) and the probe member aperture 348 (shown in FIG. 5), is sealably fixed within the probe member aperture 348, and extends in the interior of the inner container 302 toward the inner base portion 334 of the inner container 302. It is contemplated that the probe member 320 include one or more precursor temperature sensor 386, that the one or more precursor temperature sensor 386 be disposed in communication with the controller 106 (shown in FIG. 1), and the one or more precursor temperature sensor 386 be configured to provide the liquid precursor temperature measurement 248 (shown in FIG. 8) to the controller 106. It is also contemplated that the probe member 320 include one or more precursor level sensor 388, that the one or more precursor level sensor 388 be disposed in communication with the controller 106, and that the one or more precursor level sensor 388 be configured to provide the liquid precursor level measurement 250 (shown in FIG. 8) to the controller 106. In certain examples, the probe member 320 may be sealably fixed within the probe member aperture 348 by weld or a fitting. In accordance with certain examples, either of the one or more precursor temperature sensor 386 and the one or more precursor level sensor 388 may be connected to the controller 106 by the wired or wireless link 162 (shown in FIG. 1). Although the one or more precursor temperature sensor 386 and the one or more precursor level sensor 388 are shown and described herein as including a certain number of sensors, it is to be understood and appreciated that probe member 320 may include fewer or additional sensors of either type and remain with the scope of the present disclosure.

With reference to FIG. 8, the controller 106 is shown according to an example of the present disclosure. In the illustrated example the controller 106 is disposed in communication with the probe member 320 and therethrough with the one or more precursor temperature sensor 386 and the one or more precursor level sensor 388 to receive the liquid precursor temperature measurement 248 and the liquid precursor level measurement 250 therefrom, respectively. As shown and described herein the controller 106 is further disposed in communication with the immersion fluid temperature sensor 326 and the VPCS 206 to receive therefrom the immersion fluid temperature measurement 252 and the precursor concentration measurement 234 therefrom, respectively. As will be appreciated by those of skill in the art in view of the present disclosure, the controller 106 may be in communication with fewer and/or other sensors than shown and described herein, and remain within the scope of the present disclosure.

In the illustrated example the controller 106 is operatively connected to the carrier gas MFC or PC 204, the vaporized liquid precursor MFC 208, the TEC 330, and the changeover arrangement 256. In this respect it is contemplated that the controller 106 provide the carrier gas flow rate target 230 to the carrier gas MFC or PC 204 to throttle flow rate of the carrier gas 228 (shown in FIG. 3) to the liquid precursor container 300 (shown in FIG. 1). In further respect, it is further contemplated that the controller 106 provide the vaporized liquid precursor flow rate target 236 to the vaporized liquid precursor MFC 208 to throttle flow rate of the flow of the vaporized liquid precursor 10 (shown in FIG. 1) provided to the gas phase reactor 102 (shown in FIG. 1), that the controller 106 provide the TEC drive current 246 to the TEC 330 to throttle heat transfer between the liquid precursor 238 (shown in FIG. 3) contained within the liquid precursor container 300 and liquid coolant 244 (shown in FIG. 3) provided to the liquid precursor container 300, and that the controller 106 provide the changeover signal 262 to switch source of the vaporized liquid precursor 10 (shown in FIG. 1) between the first liquid precursor container 300 and the second liquid precursor container 254 (shown in FIG. 3). Although shown and described herein as being operatively connected to certain devices, it is to be understood and appreciated that the controller 106 may be operatively connected to other devices and/or fewer devices than shown and described herein and remain within the scope of the present disclosure.

In certain examples, the controller 106 may compare the liquid precursor temperature measurement 248 to a predetermined precursor temperature, for example, a predetermined precursor temperature value recorded in one of the plurality of program modules 164 (shown in FIG. 2) recorded on the memory 160 (shown in FIG. 2). When the differential exceeds the predetermined precursor temperature differential, the controller 106 may throttle (e.g., increase or decrease) rate of heat transfer between the liquid precursor 238 (shown in FIG. 3) contained within the liquid precursor container 300 (shown in FIG. 1) and the external environment outside of the liquid precursor container 300 through the liquid coolant 244 (shown in FIG. 3). Throttling may be accomplished by throttling the TEC drive current 246. Throttling may be accomplished by throttling flow rate and/or temperature of the liquid coolant 244 traversing the chill plate 332. And throttling may be accomplished using both the TEC drive current 246 and flow rate and/or temperature of the liquid coolant 244. When a differential between the liquid precursor temperature measurement 248 and the predetermined precursor temperature is less than a predetermined precursor temperature differential (e.g., recorded in one of the plurality of program modules 164), the controller 106 may leave the rate of heat transfer unchanged, and precursor temperature monitoring may continue. In accordance with certain examples, the predetermined temperature differential may correspond to a precursor concentration range wherein the VPCS 206 is accurate, for example, a range wherein the precursor concentration measurement 234 varies linearly with change in concentration of vaporized liquid precursor entrained with carrier gas within the flow of the vaporized liquid precursor 10 (shown in FIG. 1).

In certain examples, the controller 106 may compare the immersion fluid temperature measurement 252 to a predetermined immersion temperature value, e.g., a predetermined immersion fluid value recorded in one of the plurality of program modules 164 (shown in FIG. 2) recorded on the memory 160 (shown in FIG. 2). When the immersion fluid temperature measurement 252 differs from the predetermined immersion fluid value by more than a predetermined immersion fluid temperature differential value, e.g., a predetermined immersion fluid temperature differential value recorded in one of the plurality of program modules 164 recorded on the memory 160, the controller 106 may throttle the TEC drive current 246. When the predetermined immersion temperature is less than the predetermined immersion fluid temperature differential value, the controller 106 may not throttle the TEC drive current 246. Advantageously, throttling the TEC drive current 246 based on immersion fluid temperature measurement 252 in addition to the liquid precursor temperature measurement 248 may limit variation in precursor partial pressure within vaporized liquid precursor resident within the inner container ullage space 310 (shown in FIG. 7) resultant from temperature hysteresis of metallic material 340 (shown in FIG. 7) forming the inner container 302 (shown in FIG. 7). As will be appreciated by those of skill in the art in view of the present disclosure, this allows the inner container 302 to be formed from materials that have a relatively low heat transfer coefficient relatively to aluminum alloys and good corrosion resistance (e.g., stainless steel).

In certain examples, the controller 106 may compare the liquid precursor level measurement 250 to a predetermined liquid precursor value, e.g., a predetermined liquid precursor level value recorded on one of the plurality of program modules 164 (shown in FIG. 2) recorded on the memory 160 (shown in FIG. 2). When the predetermined liquid level is less than the predetermined liquid level value the controller 106 may provide a user output to a user interface, e.g., the user interface 158 (shown in FIG. 2), for example to alert a user of an approaching need to replace the liquid precursor container 300 (shown in FIG. 1). In accordance with certain examples, the controller 106 may provide the changeover signal 262, which may initiate changeover between one of the first liquid precursor container 300 and the second liquid precursor container 254 and the other of the first liquid precursor container 300 and the second liquid precursor container 254.

In certain examples, the controller 106 may offset either (or both) the predetermined liquid precursor temperature value and the predetermined immersion temperature value recorded on the one or more of the plurality of program modules 164 recorded on the memory 160 using the liquid precursor level measurement 250. Alternatively (or additionally), the controller 106 may adjust either (or both) the liquid precursor temperature measurement 248 and the immersion fluid temperature measurement 252 using the liquid precursor level measurement 250. As will be appreciated by those of skill in the art in view of the present disclosure, this can limit the risk that throttling of the rate of heat transfer between the liquid precursor 238 and the external environment outside of the liquid precursor container 300 using the liquid coolant 244 (shown in FIG. 3) overshoots due to difference in thermal mass of vaporized liquid precursor resident within the inner container ullage space 310 and the liquid precursor 238 contained within the liquid precursor container 300.

With reference to FIGS. 9-13, the material layer deposition method 400 is shown. As shown in FIG. 9, the method 400 includes vaporizing a liquid precursor contained within a liquid precursor container, e.g., the liquid precursor container 300 (shown in FIG. 1), as shown with box 402. The method 400 also includes transferring heat between a liquid precursor contained within the liquid precursor container, e.g., the liquid precursor 238 (shown in FIG. 3), and an environment outside of the liquid precursor container, e.g., the external environment 12 (shown in FIG. 1), using a at least one of a liquid precursor temperature measurement and a liquid precursor level measurement, e.g., the liquid precursor temperature measurement 248 (shown in FIG. 8) and the immersion fluid temperature measurement 252 (shown in FIG. 8), for example by communicating heat into the liquid precursor container or communicating heat from the liquid precursor container to the external environment outside of the liquid precursor container, as shown with box 404. The method 400 further includes providing a flow of a vaporized liquid precursor to a substrate supported within a gas phase reactor and depositing a material layer onto the substrate using an epitaxial deposition technique, e.g., the material layer 4 (shown in FIG. 1) deposited onto the substrate 2 (shown in FIG. 1) using the flow of the vaporized liquid precursor 10 (shown in FIG. 1), as shown with box 406 and box 408. The method 400 additionally includes refilling the liquid precursor container with additional liquid precursor, as shown with box 410. It is contemplated that the liquid precursor container 300 may be cyclically refilled during deposition, e.g., during successive deposition operations, as shown with arrow 412.

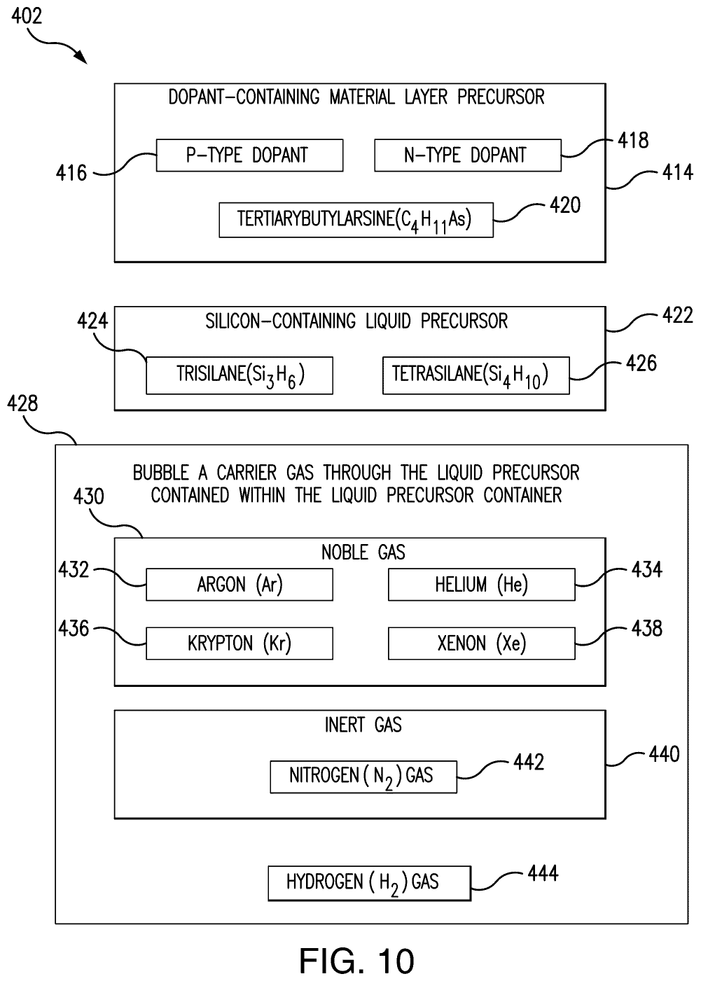

As shown in FIG. 10, vaporizing 402 the liquid precursor may include vaporizing the liquid precursor may comprise (or consist of or consist essentially of) a dopant-containing liquid precursor, as shown with box 414. The dopant-containing liquid precursor may include a p-type dopant or an n-type dopant, as shown with box 416 and box 418. Vaporizing 402 the liquid precursor may include vaporizing such as tertiarybutylarsine (C₄H₁₁As), as shown with box 420. Vaporizing 402 the liquid precursor may include vaporizing a liquid precursor comprising (or consisting of or consisting essentially of) a silicon-containing precursor, as shown with box 422. For example, trisilane (Si₃H₆) or tetrasilane (Si₄H₁₀) contained within the liquid precursor container may be vaporized to make the flow of vaporized liquid precursor provided to the gas phase reactor, as shown with box 424 and box 426.

Vaporizing 402 the liquid precursor may include bubbling a carrier gas through the liquid precursor, as shown with box 428. The carrier gas may comprise (or consist of or consist essentially of) hydrogen (H₂) gas, as shown with box 430. The carrier gas may include (or consist of or consist essentially of) a noble gas such as argon (Ar), krypton (Kr), xenon (Xe), and helium (He), as shown with boxes 430 through 438. The carrier gas may include (or consist of or consist essentially of) an inert gas, such as nitrogen (N₂) gas, as shown with box 440 and box 442. The carrier gas may include (or consist of or consist essentially of) hydrogen (H₂) gas, as shown with box 444. It is also contemplated that the liquid precursor may be vaporized using a mixture including one or more of the aforementioned carrier gases and remain within the scope of the present disclosure, as shown with box 424.

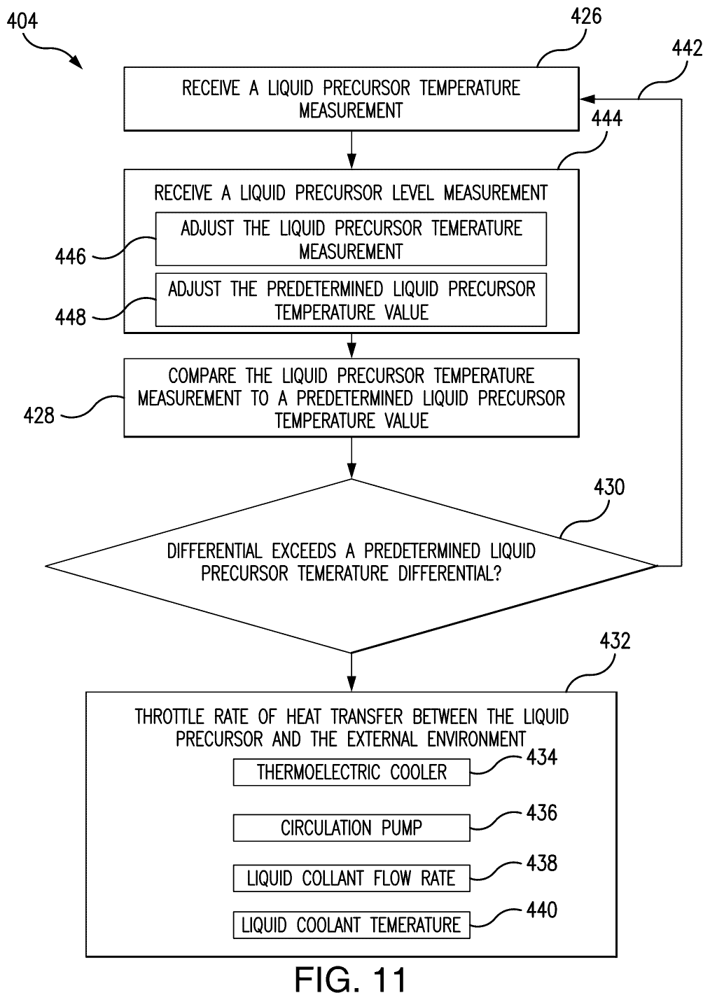

As shown in FIG. 11, transferring heat between the liquid precursor contained within the liquid precursor container and the external environment may include receiving a liquid precursor temperature measurement from the liquid precursor container, e.g., the liquid precursor temperature measurement 248 (shown in FIG. 8), as shown with box 426. The liquid precursor temperature measurement may be compared to a predetermined liquid precursor temperature value, as shown with box 428. When differential between the liquid precursor temperature measurement and the predetermined liquid precursor temperature value exceeds a predetermined liquid precursor temperature differential value, heat transfer between the liquid precursor and the external environment may be throttled (e.g., increased or decreased), as shown with box 430 and box 432. The rate of heat transfer may be throttled by throttling (e.g., increasing or decreasing) a TEC drive current provided to a TEC, e.g., the TEC drive current 246 (shown in FIG. 8), as shown with box 434. The rate of heat transfer may be throttled by throttling (e.g., increasing or decreasing) speed of a circulation pump circulating an immersion fluid within the liquid precursor container, e.g., the circulation pump 328 (shown in FIG. 7) circulating the immersion fluid 260 (shown in FIG. 7), as shown with box 436. The rate of heat transfer may be throttled by throttling (e.g., increasing or decreasing) one or more of flow rate and/or temperature of a liquid coolant provided a chill plate connected to the TEC, e.g., the chill plate 332 (shown in FIG. 3), as shown with box 438 and box 440. When the differential is less than the predetermined liquid precursor temperature differential value, the heat transfer rate may be left unchanged, and liquid precursor temperature monitoring may continue, as shown with arrow 442.

In certain examples, a precursor liquid level measurement may be received from the liquid precursor container, e.g., the liquid precursor level measurement 250 (shown in FIG. 8), as shown with box 444. The liquid precursor temperature measurement may be adjusted using the liquid precursor level measurement, as shown with box 446. The predetermined liquid precursor temperature value may be adjusted using the liquid precursor level measurement, as shown with box 448. Notably, adjustments to either (or both) the liquid precursor temperature measurement and the predetermined liquid precursor temperature value may be adjusted (e.g., to adjust for thermal mass change in the liquid precursor contained within the liquid precursor container) irrespective of whether the heat transfer rate between the liquid precursor and the external environment is throttled due to the differential, as also shown by box 444.

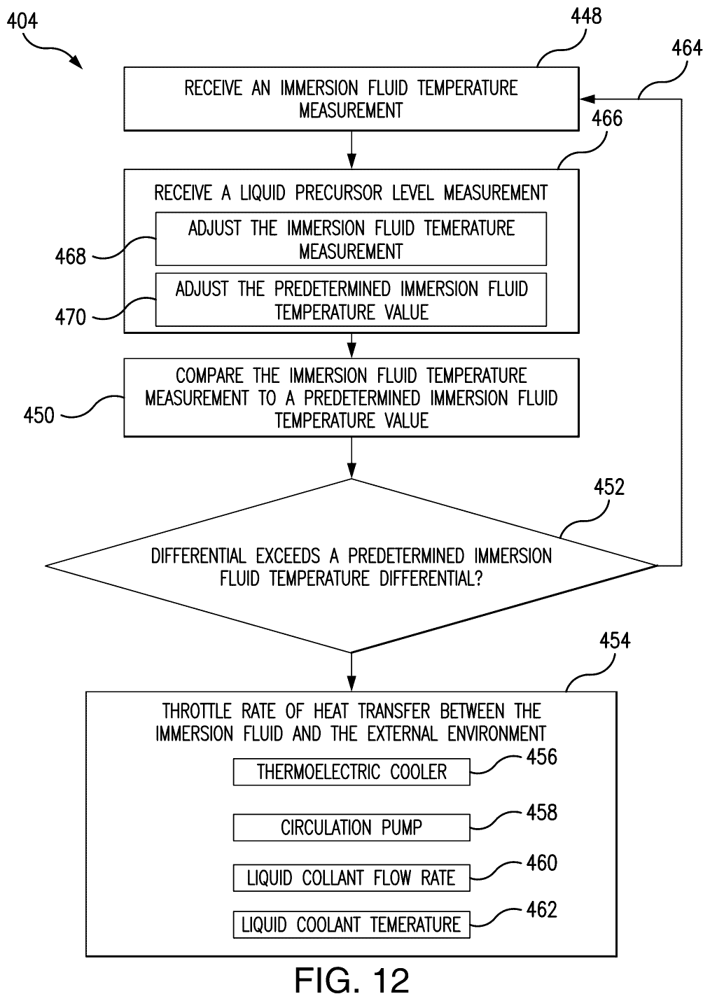

As shown in FIG. 12, transferring heat between the liquid precursor contained within the liquid precursor container and the external environment may include receiving an immersion fluid temperature measurement, e.g., the immersion fluid temperature measurement 252 (shown in FIG. 8), as shown with box 448. The immersion fluid temperature measurement may be compared to a predetermined immersion fluid temperature value, as shown with box 450. When differential between the immersion fluid temperature measurement and the predetermined immersion fluid temperature value exceeds a predetermined immersion fluid temperature differential heat transfer between the immersion fluid and the external environment may be throttled (e.g., increased or decreased), as shown with box 452 and box 454. The rate of heat transfer may be throttled by throttling (e.g., increasing or decreasing) the drive current provided to the TEC, as shown with box 456. The rate of heat transfer may be throttled by throttling (e.g., increasing or decreasing) speed of a circulation pump circulating the immersion fluid within the liquid precursor container, as shown with box 458. The rate of heat transfer may be throttled by throttling (e.g., increasing or decreasing) one or more of flow rate and/or temperature of the liquid coolant provided to the chill plate connected to the TEC, as shown with box 460 and box 462. When the differential is less than the predetermined immersion fluid temperature differential the heat transfer rate may be left unchanged, and immersion fluid temperature monitoring may continue, as shown with arrow 464.

In certain examples, the immersion fluid temperature measurement may be adjusted using the liquid precursor level measurement, as shown with box 466 and box 468. The predetermined immersion fluid temperature value may be adjusted using the liquid precursor level measurement, as shown with box 470. Notably, adjustments to either (or both) the immersion fluid temperature measurement and the predetermined immersion fluid temperature value may be adjusted (e.g., to adjust for thermal mass change in the liquid precursor contained within the liquid precursor container) irrespective of whether the heat transfer rate between the liquid precursor and the external environment is throttled due to the differential, as also shown by box 466.

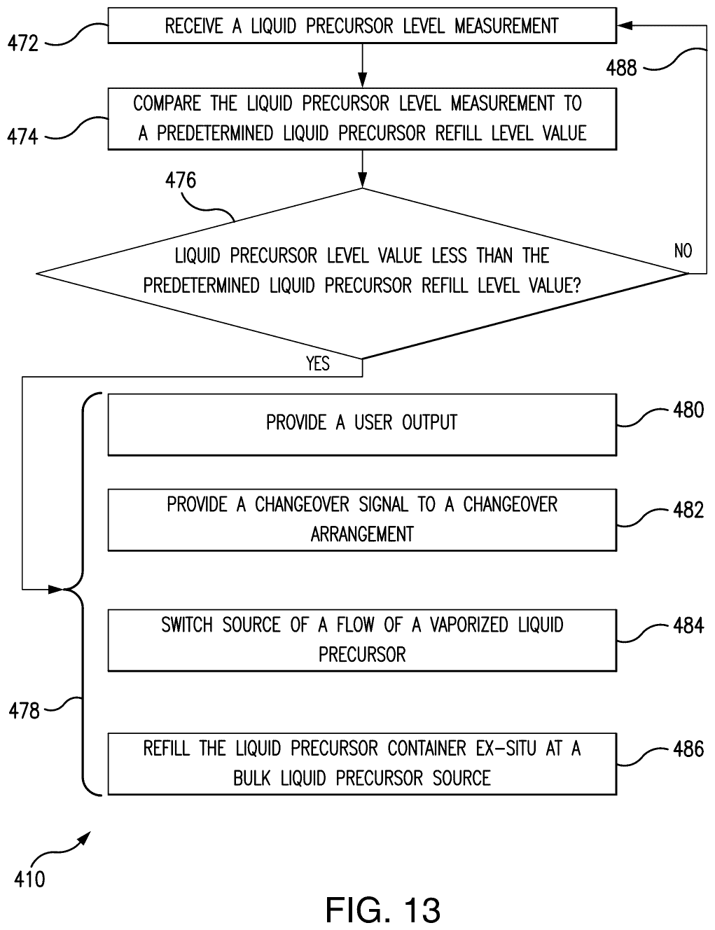

As shown in FIG. 13, refilling 410 the liquid precursor container may include receiving the liquid precursor level measurement and comparing the liquid precursor level measurement to a predetermined liquid precursor refill level value, as shown with box 472 and box 474. When the liquid precursor level measurement is less than the predetermined liquid precursor level measurement, one or more refill actions may be taken, as shown with box 476 and bracket 478. In certain examples, a user output may be provided to a user interface, e.g., to the user interface 158 (shown in FIG. 2), as shown with box 480. In accordance with certain examples, a changeover signal may be provided to a changeover arrangement, e.g., the changeover signal 262 (shown in FIG. 8), and source of vaporized liquid precursor provided to the gas phase reactor changed, as shown with box 482 and box 484. It is also contemplated that the liquid precursor container may be refilled at a bulk liquid precursor source, e.g., the bulk liquid precursor source 224 (shown in FIG. 3), as shown with box 486. In this respect the liquid precursor container may be removed from the semiconductor processing system including the gas phase reactor manually, and refilled at the bulk liquid precursor source ex-situ from the semiconductor processing system. When the liquid precursor level measurement is not below the predetermined liquid precursor refill value, monitoring may continue, as shown with arrow 488.

Material layers, such as doped silicon-containing material layers, may be deposited onto substrates by providing a dopant-containing precursor to exposing the substrate to dopant-containing gaseous precursor (i.e., a dopant-containing reactor that assumes a gaseous state under standard atmospheric pressure and temperature) in a gas phase reactor. While generally acceptable for their intended purpose, such dopant-containing precursors may add cost and complexity to the semiconductor processing system incorporating the gas phase reactor due to hazards potentially posed by the dopant-containing gaseous precursor relative to liquid precursors (i.e., precursors that assume a liquid state under standard atmospheric conditions and pressure) containing the dopant.

In certain examples described herein liquid precursor containers are provided that enable generation of vaporized liquid precursor at or in close proximity gas phase reactors, limiting (or eliminating) the need specialized equipment otherwise required when the dopant is provided using a dopant-containing gaseous precursor. In accordance with certain examples, the liquid precursor may be contained within an inner container removably seated within an outer container for removal and ex-situ refilling of the inner container with liquid precursor. It is contemplated that, in accordance with certain examples, the inner container may be configured for submersion within a liquid reactive with the liquid precursor contained within the inner container without influencing the risk assessment calculation associated use of potentially reactive materials in proximity to one another due to the arrangement of the liquid precursor container, for example by forming the inner container as a U.S. Department of Transportation DOT 4B-compliant container. Advantageously, submerging the inner container within the immersion fluid enables temperature control of both the liquid precursor disposed within a lower recess of the container as well as vaporized liquid precursor resident within an inner container ullage space above the liquid precursor contained within the inner container.

In certain examples, a TEC may be connected to an outer base portion of the outer container to transfer heat between the liquid precursor and the external environment outside of the liquid precursor container, for example, through a chill plate connected to the TEC and thermally coupled therethrough to the liquid precursor through the TEC and immersion fluid within which the inner container is submerged. In accordance with certain examples, heat transfer between the liquid precursor contained within the inner container (and the vaporized liquid precursor resident within the inner container ullage space) may be throttled using a TEC drive current applied to the TEC, for example using a controller operatively connected to the TEC.

Heat transfer may be throttled using a liquid precursor temperature acquired from a liquid precursor temperature sensor submerged within the liquid precursor. Heat transfer may be throttled using an immersion fluid temperature sensor submerged within the immersion fluid. And heat transfer may be throttled by throttling speed of a circulation pump submerged within the immersion fluid and between the inner base portion of the inner container and the outer base portion of the outer container. Advantageously, heat transfer between the liquid precursor (and the vaporized liquid precursor resident within the inner container ullage space) may be throttled using the TEC such that partial pressure of the vaporized liquid precursor resident within the inner container ullage space remains within a range that a VPCS used to control mass flow of vaporized liquid precursor to the gas phase reactor is accurate as the liquid precursor is consumed during processing. This enables employment of an off-the-shelf (e.g., non-specialized) VPCS, potentially limiting cost and complexity of the semiconductor processing system employed for depositing material layers using the liquid precursor. Accuracy may enhance by compensating the temperature control process with compensation of change in thermal mass of the liquid precursor during drawdown of the liquid precursor during processing.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A liquid precursor container, comprising:
an inner container having an inner base portion, an inner intermediate portion extending upwards from the inner base portion, and an inner lid portion coupled to the inner base portion by the inner intermediate portion of the inner container;
an outer container having an outer base portion and an outer intermediate portion, the outer base portion spaced apart from the inner base portion of the inner container, the outer intermediate portion extending upwards from the outer base portion and about the inner intermediate portion of the inner container; and
a baffle member arranged between the outer container and the inner container, the baffle member extending upwards from the outer base portion of the outer container, the baffle member terminating between the inner base portion and the inner lid portion of the inner container.

2. The liquid precursor container of claim 1, wherein the inner base portion of the inner container is spaced apart from the outer base portion of the outer container by a pumping chamber, and further comprising a circulation pump arranged within the pumping chamber.

3. The liquid precursor container of claim 2, wherein the baffle member and the inner intermediate portion define therebetween an upward flow channel spanning the inner intermediate portion of the inner container, wherein the outer intermediate portion and the baffle member define therebetween a downward flow channel spanning the inner intermediate portion of the inner container, and wherein the pumping chamber fluidly couples the downward flow channel to the upward flow channel to circulate an immersion fluid about the inner container.

4. The liquid precursor container of claim 1, further comprising an immersion fluid impounded within the outer container, wherein the baffle member and the inner container are submerged within the immersion fluid.

5. The liquid precursor container of claim 1, further comprising:
a carrier gas conduit sealably fixed within the inner lid portion of the inner container and extending toward the inner base portion of the inner container;
a plug member removably fixed within the inner lid portion of the inner container;
an outlet conduit sealably fixed within the inner lid portion of the inner container; and
a probe member sealably fixed within the inner lid portion of the inner container and extending toward the inner base portion of the inner container.

6. The liquid precursor container of claim 1, further comprising:
a hinge member connected to the outer intermediate portion of the outer container;
an outer lid connected to the hinge member and movable between a first position and a second position, the outer lid separating the inner container from an external environment outside of the liquid precursor container in the first position, the inner container exposed to the external environment in the second position and removable from the outer container; and
an immersion fluid temperature sensor seated in the outer lid and extending into a downward flow channel defined between the baffle member and the outer intermediate portion of the outer container.

7. The liquid precursor container of claim 1, further comprising:
a dopant-containing liquid precursor contained within the inner container; and
an immersion fluid impounded within the outer container, wherein the inner container is submerged within the immersion fluid, and wherein the dopant-containing liquid precursor is reactive with the immersion fluid.

8. The liquid precursor container of claim 1, further comprising:
a silicon-containing liquid precursor contained within the inner container; and
an immersion fluid impounded within the outer container, wherein the inner container is submerged within the immersion fluid, and wherein the silicon-containing liquid precursor is reactive with the immersion fluid.

9. The liquid precursor container of claim 1, further comprising:
a thermoelectric cooler connected to the outer base portion of the outer container; and
a chill plate connected to the thermoelectric cooler and therethrough to the outer base portion of the outer container.

10. The liquid precursor container of claim 1, further comprising:
a carrier gas source connected to the inner container; and
a gas phase reactor having a single-wafer crossflow arrangement connected to the inner container and fluidly coupled therethrough to the carrier gas source.

11. The liquid precursor container of claim 1, wherein the inner container is U.S. DOT 4B-compliant, wherein the outer container is not U.S. DOT 4B-compliant.

12. A liquid precursor system, comprising:
an enclosure body having ventilated chamber with a container seat;
a liquid precursor container as recited in claim 1, wherein the liquid precursor container is arranged within the ventilated chamber and removably supported at the container seat;
a vent source connected to the ventilated chamber;
a coolant circuit connected to the liquid precursor container; and
a coolant source connected to coolant circuit, wherein the coolant source is remote from the enclosure body.

13. The liquid precursor system of claim 12, wherein the liquid precursor container is connected to a gas phase reactor, wherein the enclosure body is than about three (3) meters from the gas phase reactor.

14. The liquid precursor system of claim 12, further comprising:
a carrier gas mass flow controller (MFC) connected to the inner container;
a vapor pressure concentration sensor (VPCS) connected the inner container and fluidly coupled by the inner container to the carrier gas MFC;
a vaporized liquid precursor MFC connected to the VPCS and therethrough to the carrier gas MFC via the inner container; and
a liquid precursor contained within the liquid precursor container selected from a group including trisilane (Si₃H₆), tetrasilane (Si₄H₁₀), trichlorosilane (HCl₃Si), and tertiarybutylarsine (C₄H₁₁As).

15. The liquid precursor system of claim 12, wherein the container seat is a first container seat, wherein the liquid precursor container is a first liquid precursor container, and wherein the liquid precursor system further comprises:
a second liquid precursor container removably fixed at a second container seat; and
a changeover arrangement connecting the second liquid precursor container with the first liquid precursor container.

16. A material layer deposition method, comprising:
at a semiconductor processing system including a gas phase reactor and a liquid precursor container including an inner container having an inner base portion, an inner intermediate portion extending upwards from the inner base portion, and an inner lid portion coupled to the inner base portion by the inner intermediate portion of the inner container; an outer container having an outer base portion and an outer intermediate portion, the outer base portion spaced apart from the inner base portion of the inner container, the outer intermediate portion extending upwards from the outer base portion and about the inner intermediate portion of the inner container; and a baffle member arranged between the outer container and the inner container, the baffle member extending upwards from the outer base portion of the outer container, the baffle member terminating between the inner base portion and the inner lid portion of the inner container,
vaporizing a liquid precursor contained within the inner container;
providing a flow of the vaporized liquid precursor to the gas phase reactor; and
depositing a material layer onto a substrate using the vaporized liquid precursor with an epitaxial deposition technique.

17. The material layer deposition method of claim 16, further comprising:
transferring heat between the liquid precursor and an external environment outside of the liquid precursor container by:
receiving a liquid precursor temperature measurement indicative of temperature of the liquid precursor contained within the inner container;
comparing the liquid precursor temperature measurement to a predetermined liquid precursor temperature value; and
throttling heat transfer between the liquid precursor and an environment external to the liquid precursor container using a thermoelectric cooler connected to the outer base portion of the outer container when differential between the liquid precursor temperature measurement and the predetermined liquid precursor temperature value is greater than a predetermined liquid precursor temperature differential value.

18. The material layer deposition method of claim 17, further comprising:
receiving a liquid precursor level measurement indicative of level of the liquid precursor contained within the liquid precursor container; and
adjusting at least one of (a) the liquid precursor temperature measurement, and (b) the predetermined liquid precursor temperature value using the liquid precursor level measurement.

19. The material layer deposition method of claim 16, further comprising:
transferring heat between an immersion fluid impounded within the outer container and within which the inner container is submerged and an external environment by:
receiving an immersion fluid temperature measurement indicative of temperature of the immersion fluid;
comparing the immersion fluid temperature measurement to a predetermined immersion fluid temperature value; and
throttling heat transfer between the immersion fluid and the external environment external to the liquid precursor container using a thermoelectric cooler when differential between the immersion fluid and the predetermined immersion fluid temperature value is greater than a predetermined immersion fluid differential value.

20. The material layer deposition method of claim 16, further comprising:
receiving a liquid precursor level measurement indicative of liquid precursor level within the inner container;
comparing the liquid precursor level measurement to a predetermined liquid precursor level measurement; and
at least one of (a) providing a user output to a user interface, (b) providing a changeover to a changeover arrangement to switch source of the vaporized liquid precursor, and (c) refill the inner container ex-situ with additional liquid precursor.
